(19) United States
(12) Patent Application Publication
(10) Pub. No.: US 2026/0129806 A1
(43) Pub. Date: May 7, 2026

(54) RACK WITH VENTALATION ASSEMBLY

(71) Applicant: Aivres Systems Inc., Fremont, CA (US)

(72) Inventor: Ching-Wen Hsiao, New Taipei City (TW)

(73) Assignee: Aivres Systems Inc., Fremont, CA (US)

(21) Appl. No.: 19/436,786

(22) Filed: Dec. 30, 2025

(51) Int. Cl. H05K 7/20

(52) U.S. Cl. CPC H05K 7/20709

(57) ABSTRACT

A ventilation assembly for use with a storage rack having receiving bays for receiving computing system is configurable between a closed configuration blocking airflow to the receiving bays and an opened configuration permitting airflow to the receiving bays. The ventilation assembly includes a plurality of louvers pivotally swinging between orientations perpendicular to an installation direction of the computing system and parallel to the installation direction to provide louver gaps permitting airflow to the receiving bay. The ventilation assembly includes an actuation linkage converting movement of the computing system in the installation direction to pivot the plurality of louvers to the opened configuration.

### TECHNICAL FIELD

The present disclosure relates to a storage rack for accommodating a plurality of computing systems and more particularly to a ventilation system for the circulation of airflow within the storage rack.

### BACKGROUND

Data centers are locations that accommodate a plurality of individual computing systems in an enclosed and secure room. The computing systems may be computer servers such as data servers for maintaining large quantities of data and information, for example, to support database applications, web servers for supporting the internet, and application servers on which computer applications can run in, for example, a cloud-based environment. The data centers provide resources such as electrical power and environmental controls for the plurality of individual computing systems.

To arrange and organize the computing systems, storage racks comprising a plurality of receiving bays are located in the data centers. Storage racks, also referred to as server racks, are the structural framework defining the receiving bays in which the individual computing units can be mounted, typically in a stacked vertical arrangement although side-by-side arrangements are also possible. The receiving bays are accessible through a rack front face and the individual computing system can be inserted into the storage rack in an installation direction.

To remove the substantial amount of heat generated by operating several computing systems simultaneously, the data centers are often configured to provide ventilation and cooling. For example, the storage racks may be arranged side-by-side in rows, and multiple rows may be separated by one or more aisles. A designated cold aisle can receive cold airflow, for example, from an air conditioning unit and a designated hot aisle can be associated with one or more vents to discharge the heated air from the data center. Airflow can pass from the cold aisle into the receiving bays through the rack front face and be discharged to the hot aisle from the rack rear face. The disclosure is directed at improving ventilation within storage racks.

### SUMMARY OF THE DISCLOSURE

The disclosure describes a storage rack including a rack frame with a plurality of receiving bays for each receiving a computing system inserted in an installation direction. To ventilate the receiving bays, the storage rack includes a ventilation assembly at the rear rack face. The ventilation assembly includes a louver frame extending in a lateral direction perpendicular to the installation direction and a louver subassembly having a plurality of louvers each pivotally joined to the louver frame. The louver subassembly is configurable between a closed configuration with the plurality of louvers occluding the receiving bay and an opened configuration with the plurality of louvers pivoted to provide louver gaps accessing the receiving bay. To swing the plurality of louvers between the closed and opened configurations, the ventilation system includes an actuation linkage operatively configured to convert motion in the installation direction to pivot each of the plurality of louvers.

In a further aspect, the actuation linkage comprises a pushrod displaceable in the installation direction and a connecting rod connecting each of the plurality of louvers, the pushrod and the connecting rod being operatively connected to each other.

In a further aspect, the actuation linkage includes a first coupler link and a second coupler link connecting the pushrod and the connecting rod.

In a further aspect the pushrod includes a distal end connected to the first coupler link and a proximal end connected to the second coupler link.

In a further aspect, the actuation linkage includes a roller journaled to the proximal end.

In a further aspect, each of the plurality of louvers includes a louver pane and a swing arm intersecting at a fixed angle.

In a further aspect, pivoting of the plurality of louvers swings the louver panes from being perpendicular to the installation direction in the closed configuration to being parallel to the installation direction in the opened configuration.

In a further aspect, the louver panes of each of the plurality of louvers are aligned in the lateral direction in the closed configuration.

In a further aspect, each of the plurality of louvers is connected by a connecting axle to a connecting rod operatively associated with the actuation linkage.

In a further aspect, the actuation linkage further comprises a biasing spring biasing the louver subassembly to the closed configuration.

The disclosure also provides a method of ventilating a storage rack that defines a plurality of receiving bays for receiving computing systems. The method includes inserting a computing system into a receiving bay in an installation direction extending between a rack front face and a rack rear face. Installation of the computing system moves a pushrod of a ventilation system in the installation direction in response to abutting contact with the computing system. Movement of the pushrod in the installation direction is converted to movement of a connecting rod of the ventilation system in a lateral direction that pivots a plurality of louvers, each operatively connected to the connecting rod, from a closed configuration parallel with the lateral direction to an opened configuration parallel with the installation direction.

In a further aspect, the method includes compressing a biasing spring operatively connecting between the pushrod and a louver subassembly comprised of the plurality of louvers by movement of the pushrod.

In a further aspect, the method includes pivoting the plurality of louvers from the opened configuration to the closed configuration by releasing the biasing spring.

In a further aspect, the installation direction and the lateral direction are perpendicular to each other.

The disclosure also provides a ventilation assembly for a storage rack for mounting a plurality of computing system. The ventilation system includes a louver frame extending in a lateral direction and mountable between two vertical posts of a rack frame and a louver subassembly having a plurality of louvers pivotally joined to the louver frame. Each of the plurality of louvers includes a louver pane and a swing arm intersecting each other at a fixed angle. Each of the plurality of louvers is swingable to pivot the louver panes from being parallel in the lateral direction in a closed configuration to an opened configuration. To swing the plurality of louvers, the ventilation system includes an actuation linkage comprising a pushrod displaceable in an installation direction and a connecting rod connecting the plurality of louvers. The pushrod and the connecting rod are operatively connected so that displacement of the pushrod in the installation direction swings each louver pane of the plurality of louvers from the closed configuration to the opened configuration.

In a further aspect, each louver pane of the plurality of louvers is parallel to the installation direction in the opened configuration.

In a further aspect, the lateral direction and the installation direction are perpendicular.

In a further aspect, the connecting rod moves in the lateral direction upon displacement of the pushrod in the installation direction.

In a further aspect, each swing arm is connected to the connecting rod by a connecting axle.

In a further aspect, a biasing spring is operatively connected between the louver subassembly and the actuation linkage to bias the plurality of louvers to the closed configuration.

### BRIEF DESCRIPTION OF THE DRAWINGS

FIG. 1 is a perspective view of a storage rack defining a plurality of receiving bays to accommodate individual computing systems in a data center in accordance with the disclosure.

FIG. 2 is a perspective view of a ventilation assembly for the storage rack comprising a louver subassembly with a plurality of louvers pivoted to a closed configuration with respect to a louver frame.

FIG. 3 is a perspective view of the ventilation assembly for the storage rack with the plurality of louvers of the louver subassembly pivoted to an opened configuration with respect to the louver frame.

FIG. 4 is a perspective view of a louver including a louver pane and a swing arm intersecting at a fixed angle and adapted to swing with respect to a pintle.

FIG. 5 is a perspective view of the louver frame including a crosspiece and a plurality of pintles for pivotally connecting with the louvers.

FIG. 6 is a perspective view of the actuation linkage for converting installation of the computing systems to cause the plurality of louvers to pivotally swing between the closed and opened configurations.

FIG. 7 is a perspective view of the ventilation system in the closed configuration with a biasing spring operatively fixed in relation to louvers and the actuation linkage.

FIG. 8 is a perspective view of the biasing spring compressed by actuation of the ventilation system to the opened configuration.

FIG. 9 is a perspective view of the ventilation assembly with the louver subassembly in the closed configuration and the plurality of louvers pivotally swung to block ventilation to the receiving bay.

FIG. 10 is a perspective view illustrating the plurality of louvers swung to the opened configuration upon installation of the computing system to allow ventilation airflow through the receiving bay.

### DETAILED DESCRIPTION

The following detailed description is exemplary in nature and is not intended to limit the disclosure or the application and uses of the described embodiments. Furthermore, there is no intention to be bound by any expressed or implied theory presented in the preceding background, summary and brief description of the drawings, or the following detailed description. Numerous specific details are set forth in order to provide a more thorough understanding of the disclosed technology. However, it will be apparent to one of ordinary skill in the art that the disclosed technology may be practiced without these specific details. In other instances, well-known features have not been described in detail to avoid unnecessarily complicating the description.

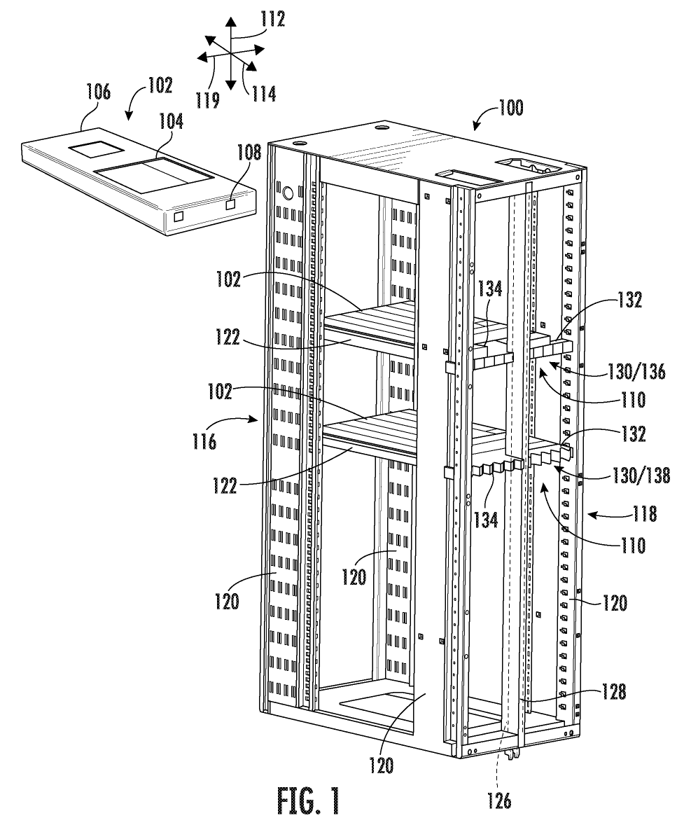

Referring to FIG. 1, wherein like reference numbers refer to like elements whenever possible, there is illustrated an example of a storage rack 100 designed to accommodate a plurality of individual computing systems 102, which may be servers such as blade servers. The computing systems 102 can each have an outer enclosure or chassis 104 that houses the circuitry and electronic components for the system. The chassis 104 can include a chassis front 106 or forward panel with control and power switches, buttons and readouts, and a chassis rear 108 or rear panel that may include input/output ports and connectors and possibly vents for airflow through the chassis 104.

The chassis 104 may be configured in a standardized size and format and is designed to be rack-mountable in the storage rack 100 with several other computing systems 102. For example, the storage rack 100 can define a plurality of receiving bays 110 that are arranged in a vertically stacked configuration extending a vertical direction 112. A computing system 102 can be inserted into a corresponding receiving bay 110 in an installation direction 114 perpendicular to the vertical direction 112. The computing system 102 may be installed so that the chassis front 106 aligns with a rack front face 116 of the storage rack 100 and the chassis rear 108 is oriented toward a rack rear face 118. The installation direction 114 extends between the rack front face 116 and the rack rear face 118, and the storage rack 100 may be designed so that installation and removal of the computing systems 100 into and from the receiving bays 110 occurs through the rack front face 116. The storage rack 100 can also have a lateral direction 119 orthogonal to the vertical and installation directions 112, 114 and that aligns with the horizontal width of the receiving bays 110.

To provide the structural framework for defining the receiving bays 110 and mounting the computing systems 102, the storage rack 100 can be comprised of a plurality of upright posts (also referred to as vertical posts) 120 that extend parallel to the vertical direction 112. The illustrated storage rack 100 is a four-post design having four upright posts 120 in a quadrilateral arrangement with each post corresponding to a respective one of the corners of the cubic rack for strength and stability, however, 2-post racks are also a common design. The upright posts 120 are connected by horizontal rails 122 arranged orthogonally to the vertical direction and that structurally fixed the quadrilateral arrangement of the storage rack 100. In an embodiment, the horizontal rails 122 that are configured to support one of the computing systems 102. For example, the horizontal rails 122 may align with and contact the lateral sides of the chassis 104 to vertically hold the computing system 102 in the storage rack 100. In possible embodiments, the horizontal rails 122 can be equipped with a slide mechanism including rollers and tracks that allow the computing system 102 to be pulled from and inserted into the receiving bays 110.

The locations of the horizontal rails 122 can correspond to the location of each receiving bay 110 and the height between the horizontal rails 122 in the vertical direction 116 may be associated with standardized dimensions of the computing systems 102. For example, each rack unit (U) of 1.75 inches may correspond to an industry standard height of a blade server. To accommodate computing systems 102 of different heights, the upright posts 120 can be perforated with a plurality of dowel holes that allow changes to the locations where the horizontal rails 122 connect to the upright posts 120 and the vertical dimensions of the receiving bays 110 can be adjusted.

The storage rack 100 can be an open-frame design in which the upright posts 120 and the horizontal rails 122 providing the structural framework of the storage rack are exposed. The plurality of receiving bays 110 are accordingly generally opened to the environment for accessibility. Another example of a rack design in accordance with the disclosure are cabinets or enclosures in which planar panels are attached to the structural framework of the storage rack 110 generally enclosing the plurality of receiving bays 110. To access the receiving bays 110, the front rack face 116 can be associated with a door attached by hinges to one of the upright posts 120.

To supply electrical power to the plurality of computing systems 102 individually received in each of the plurality of receiving bays 110, the storage rack 100 can include a busbar 126. The busbar 126 is an elongated strip or bar of metal for conducting high current power distribution. The busbar 126 can be attached to the rear rack face 118 and can extend in the vertically direction 112 to traverse vertically across the plurality of receiving bays 110. Because of the openwork configuration of the storage rack 100, the busbar 126 is accessible from the rear of the receiving bays 110 and can make electrical connection with a computing system 102 installed in the installation direction 114.

For protection and isolation, the conductive busbar 126 can be accommodated within an insulative channel 128 that fits around the busbar and that extends in the vertical direction 112. The busbar 126 and the insulative channel 128 can be located on the rack rear face 118 mid -width of the plurality of receiving bays 110 with respect to the lateral direction 119. In other configurations, electrical power can be supplied to the computing systems 102 located in the receiving bays 110 by conductive electrical cables which may be attached along the framework of the storage rack 100.

To assist airflow through the plurality of receiving bays 110 in either the open rack or cabinet designs, the storage rack 100 can be associated with ventilation structures such as baffles and vane guides. For example, in the illustrated embodiment, the storage rack 100 can include one or more ventilation assemblies 130 that are attached at the rack rear face 118. The ventilation assemblies 130 can be each associated with a corresponding one of the plurality of receiving bays 110 as defined by the horizontal rails 122 spaced vertically in the vertical direction. In other embodiments, each ventilation assembly 130 may be operatively associated with and vertically traverse several receiving bays 110.

The ventilation assemblies 130 can be aligned parallel to the lateral direction 119 and can extend between two upright posts 120 that are located laterally opposite each other. The ventilation assemblies 130 are accordingly perpendicular to the installation direction 114 and traverse across the width of the receiving bays 110 in the lateral direction 119. The ventilation assemblies 130 can be attached to the upright posts 120 by fasteners or clips to fixate their location on the rack rear face 118 with respect to the receiving bays 110. If the storage rack 100 includes the busbar 126, the ventilation assemblies 130 may be split into first and second assembly halves 132, 134. The first and second assembly halves 132, 134 can laterally mirror each other with respect to the busbar 126 that bifurcates the ventilation assemblies in the vertical direction 120.

The ventilation assemblies 130 are configured to selectively switch between a closed configuration 136 occluding access to the corresponding receiving bay 110 and an open configuration 138 permitting airflow through the rack rear face 118. For example, as shown in the top location, the ventilation assembly 130 in the closed configuration 136 is flush with the rear rack face 118 enclosing the receiving bay 110 in the installation direction 114. In the opened configuration 138 at the bottom location, the ventilation assembly 130 adjusts to provide a plurality of gaps through the rack rear face 118 venting the receiving bays 110.

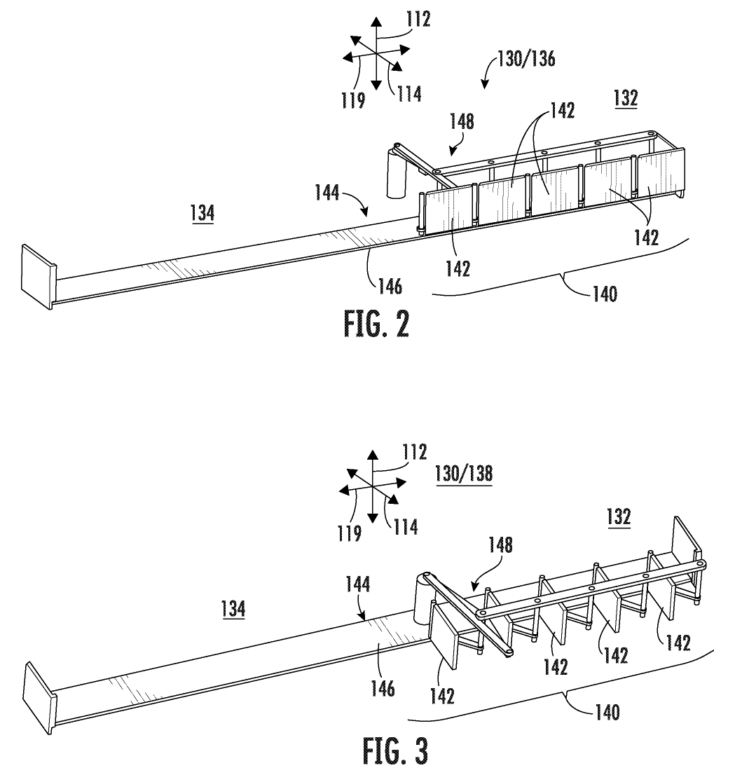

Referring to FIGS. 2 and 3, one of the first and second assembly halves 132, 134 of the ventilation assembly 130 is shown unattached to the storage rack. FIG. 2 shows the ventilation assembly 130 in the closed configuration 136 and FIG. 3 shows the ventilation assembly in the opened configuration 138. Each of the first and second assembly halves 132, 134 may be comprised of operatively interconnected components that cooperatively function to selectively adjust the ventilation assembly 130 between the close and opened configurations 136, 138 upon a triggering event, for example, such as installation of the computing system into the storage rack. The components and the arrangement of the first and second assembly halves 132, 134 may mirror each other such that description of one assembly half suffices for the other.

The components parts of the ventilation assembly may include a louver subassembly 140 comprised of a plurality of louvers 142 that are arranged to pivotally swing with respect to a louver frame 144 comprising a crosspiece 146. The crosspiece 146 may be an elongated strip or flat bar of metal extending in the lateral direction 119. Each of the plurality of louvers 142 is pivotally connected to the crosspiece 146 and are laterally spaced apart from each other in the lateral direction 119. Accordingly, the louver frame 144 can be fixed stationary to the storage rack and the plurality of louvers 142 of the louver subassembly 140 are each capable of swinging with respect to the crosspiece 146 to switch between the closed and opened configurations. In the illustrated embodiment, the louver subassembly 140 includes five louvers 142 pivotally connect to the crosspiece 146 but any practical number may be included.

To collectively swing the plurality of louvers 142 between the closed configuration 136 and the opened configuration 138 by pivoting with respective to the crosspiece 146, each of the assembly halves 132, 134 of the ventilation assembly 130 can include an actuation linkage 148. The actuation linkage 148 is configured to convert an actuation force applied in the installation direction 114 to collectively pivot the plurality of louvers 142 of the louver subassembly 140 between the closed and opened configuration 136, 138.

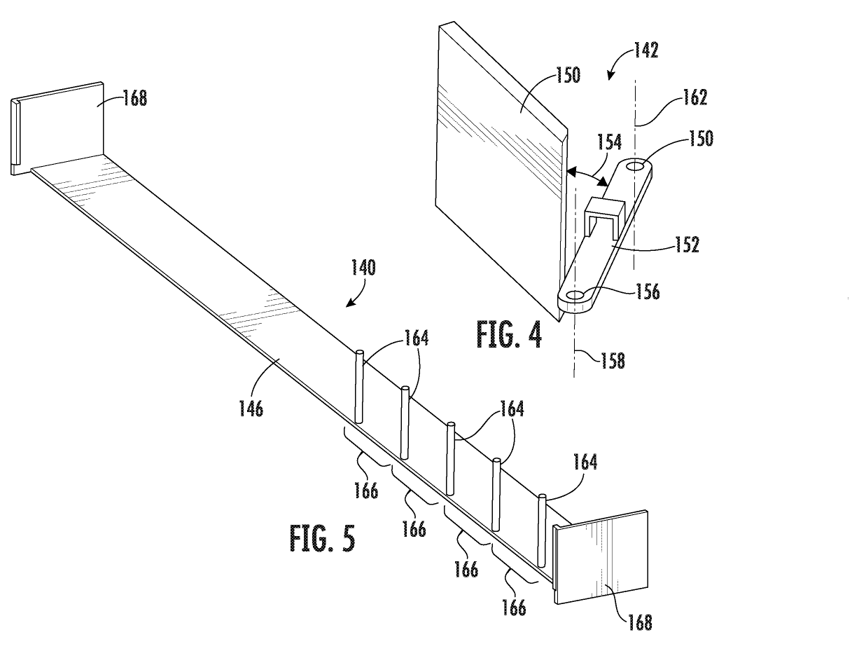

Each louver 142 is designed to align successively with the plurality of other louvers 142 of the louver subassembly 140 in the lateral direction 119 in the closed configuration 136 and to pivotally swing to be parallel to one another in the installation direction 114 in the opened configuration 138. Referring to FIG. 4, each louver 142 can include a louver pane 150 that may be a flat planar panel that is generally square or quadrilateral in shape. Joined to a lower edge of the louver pane 150 can be a swing arm 152 that may be a flat rectangular bar or rod. The swing arm 152 can intersect the louver pane 150 at an acute angle 154 so that the swing arm 152 extends acutely from the plane defined by the louver panes 150.

The louver pane 150 and the swing arm 152 can be integrally formed and can be made from molded plastic for rigidity and strength. The edges of the louver pane 150 can be straight and sharp, although in possible embodiments the edges may be chamfered to assist in swinging the plurality of louvers 142 into alignment in the louver subassembly.

The swing arm 152 can include a fixed pivot socket 156 that is located proximate to the intersection with the louver pane 150. The fixed pivot socket 156 can be a circular hole disposed through the swing arm 152 that defines a fixed pivot axis 158. The fixed pivot axis 158 can be perpendicular to the swing arm 152 and parallel with the plane defined by the louver panes 150. When the louver 142 is assembled to the ventilation assembly, the fixed pivot axis 158 can align with the vertical direction.

Located at the distal end of the swing arm 152 away from the interaction with the louver pane 150 and opposite of the fixed pivot socket 156 can be a moving pivot socket 160. The moving pivot socket 160 is also a circular hole disposed through the structure of the swing arm 152 and defines a moving pivot axis 162. The fixed pivot axis 158 and the moving pivot axis 162 are parallel with each other and may both align with the vertical direction 112. The swing arm 142 may include additional features such as a band or the like to couple to other components.

Referring to FIG. 5, to pivotally attach to the plurality of louvers 142 included with the louver subassembly, the louver frame 144 can include a corresponding plurality of pintles 164. The pintles 164 can be small diameter rods that project perpendicularly from the flat surface of the crosspiece 146. The plurality of pintles 164 can be parallel to one another and align with the vertical direction 112 when the louver frame 144 is incorporated into the ventilation assembly. The pintles 164 may be laterally spaced form each other along the crosspiece 146 in the lateral direction 119 to define pintle spaces 166 there between. The pintle spaces 166 can be sized to accommodate louver panes between adjacent pintles 164.

The louver frame 144 can include frame flanges 168 that may be located at either end of the crosspiece 146. The frame flanges 168 can extend perpendicularly from the lateral ends of the crosspiece 146 and may be orthogonal to the lateral direction 119. The frame flanges 168 may be rectilinear or quadrilateral in shape. To attach the ventilation assembly to the storage rack, the frame flanges 168 are oriented to align adjacent with the upright posts and may include connecting features like hooks, clips, or fastener accommodations. The louver frame 144 can be made from plastic or metal for stability with the crosspiece 146 and frame flanges 168 formed from bar stock and the pintles 164 fixed to the crosspiece by threads or riveted. In other embodiments, the pintles 164 can be integral to the louvers 142 and crosspiece 146 may include sockets bore to receive the pintles.

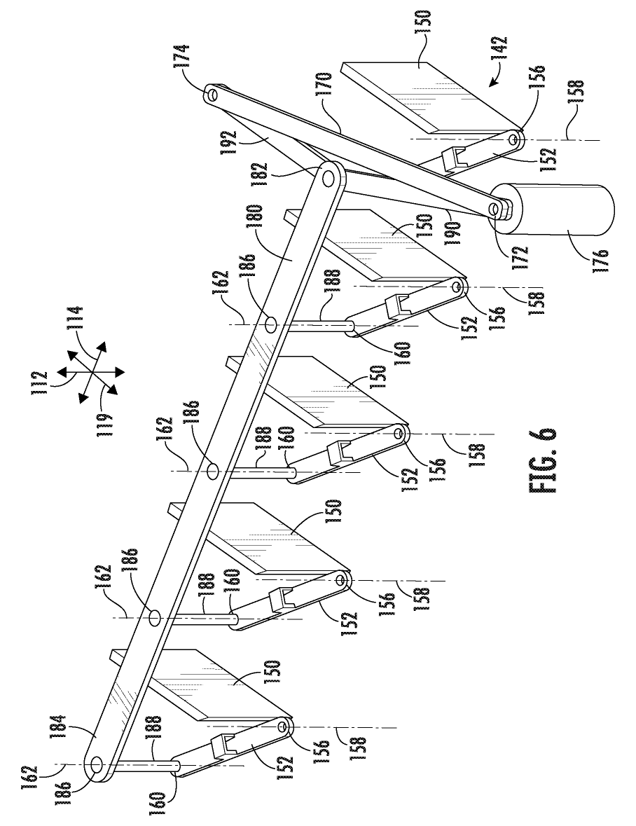

Referring to FIG. 6, the actuation linkage 148 is a mechanical assembly comprised of a plurality of rigid links that are connected together by joints that allow relative motion between the links. The rigid links may be metal or plastic for rigidity and strength. Although various geometric shapes are possible, the illustrated rigid links may be elongated linear bars of sufficient stiffness for the transfer of forces and loads without buckling. The joints interconnecting the links may be pin joints or revolute joints allowing rotation between interconnected links although other degrees of motion and sliding translation are possible.

To receive the input or actuating force, the actuation linkage 148 includes a pushrod 170 which may be an elongate slender bar or rod of flat geometry. When incorporated in the ventilation assembly, the pushrod 170 may be oriented and aligned generally in the installation direction 114 and generally perpendicular to the lateral direction 119 in which the louver subassembly 140 is aligned. The elongated shape of the pushrod 170 can extend between and define a proximal end 172 and a distal end 174 located opposite thereof.

To apply the actuation force, a roller 176 can be attached to the proximal end 172 of the pushrod 170. The roller 176 can extend perpendicularly from the proximal end 172 of the pushrod 170 in the vertical direction 112 and can be orthogonal to the installation direction 114 and accordingly is perpendicular to an actuation force applied in the installation direction. The roller 176 can be shaped as a cylindrical drum and can be rotatably journaled to the proximal end to spin or rotate with respect to the pushrod 170.

To operatively interconnect the plurality of louvers 142 of the louver subassembly 140, the actuation linkage 148 includes connecting rod 180 that may be oriented in the lateral direction 119. The connecting rod 180 can also be a slender flat bar extending between a first lateral end 182 and a second lateral end 184. The lateral distance between the first lateral end 182 and the second lateral end 184 may approximately correspond with the dimension of the louver subassembly 140 so that the connecting rod 180 can extend commensurately in the lateral direction 119 across the plurality of louvers 142.

To operatively connect to each of the louvers 142, the connecting rod 180 may include a plurality of connecting sockets 186 oriented in the vertical direction 112 and laterally spaced in the lateral direction 119. Each connecting socket 186 may be a circular hole and is positioned above the swing arms 152 and can be aligned with the moving pivot axis 162 defined by the moving pivot socket 160. To physically interconnect the connecting rod 180 and the swing arms 152, a connecting axle 188 is journalled at either end to one of the moving pivot sockets 160 of the swing arm 152 and the connecting socket 186 of the connecting rod 180. The connecting axle 188 is accordingly fixed in relation to and extends along the moving pivot axis 162 that passes through the swing arms 152.

To transfer a force applied to the pushrod 170 in the installation direction 114 to the connecting rod 180 and cause movement in the lateral direction 119, the pushrod 170 and the connecting rod 180 may be connected by a first coupler link 190 and a second coupler link 192. The first and second coupler links 190, 192 may also be slender flat rods of shorter length relative to the pushrod 170 and the connecting rod 180. The first coupler link 190 can be pivotally connected at one end to the proximal end 172 of the pushrod 170 and pivotally connected at the other end to the first lateral end 182 of the connecting rod 180. The second coupler link 192 can be connected at one end to the distal end 174 of the pushrod 170 and connected at the other end to the first lateral end 172 of the connecting rod 180.

The actuation linkage 148 assumes a triangular arrangement from the jointed connections between pushrod 170 and the first and second coupler links 190, 192. When a force or load in the installation direction 114 is applied to the roller 176, the pushrod 170 is displaced with respect to the installation direction and may tilt or lean. Displacement of the pushrod 170 is redirected and transferred through the first and second coupler links 190, 192 to the connecting rod 180 causing translation in the lateral direction 119. The first and second coupler links 190, 192 can articulate to enable movement of the connecting rod 180 in the lateral direction 119.

The connecting rod 180 may also move in the installation direction 114 due to being structurally connected with the pushrod 170. In other words, as the pushrod 170 moves in the installation direction 114, the connecting rod 180 may likewise move in the same installation direction due to the fixed spatial relation of the components. Movement of the connecting rod 180 is transferred to the louver subassembly 140 through the connecting axle 188 interconnecting the connecting rod 180 with each of the plurality of louvers 142.

In particular, when the connecting rod 180 is moved in the installation direction 114 and lateral direction 119, the swing arm 152 is caused to move in a fixed relation due to the connecting axle 188 extending along the moving pivot axis 162. The end of the swing arm 152 joined to the connected axle 188 and associated with the moving pivot axis 162 accordingly pivots in relation the fixed pivot axis 158 at the intersection between the swing arm 152 and the louver pane 150. The moving pivot axis 162 rotates partially around the fixed pivot axis 158 of the louver 142 that is stationary with respect to the storage rack 100. The louver pane 150, fixed in relation to the swing arm 152 by the fixed angle 154, is caused to swing about the fixed pivot axis 158. The swing arm 152 may also generate leverage and a mechanical advantage to swing the louver panes 150 about the fixed pivot axis 158.

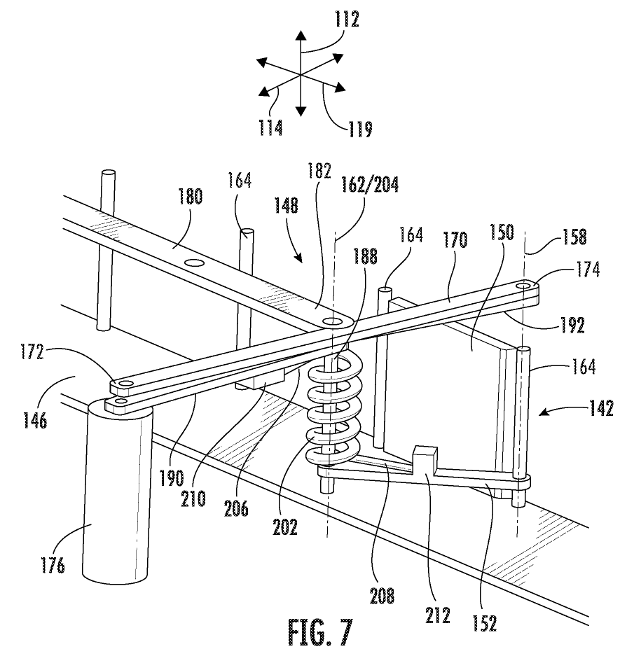

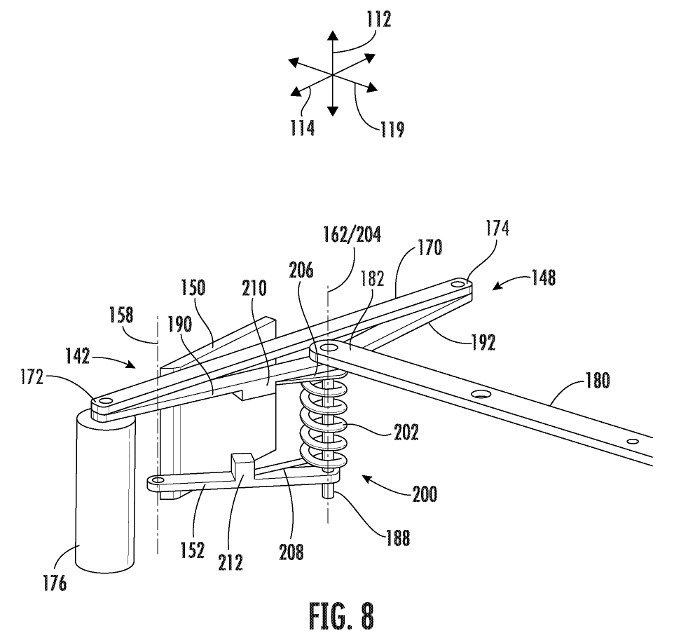

To enable actuation of the ventilation assembly 130 between the closed and opened configurations in response insertion and removal of a computing system, the actuation linkage 148 can be operatively associated with a biasing spring 200 such as, for example, a helical torsion spring. Referring to FIGS. 7 and 8, for example, the biasing spring 200, when embodied as a helical torsion spring, can be made from a long stiff wire partially wound into a helical coil 202 that defines a spring axis 204. When assembled with the actuation linkage 148, the helical coil 202 can be disposed around the connecting axles 188 that operatively connect the swing arms 152 of the louvers 142 to the connecting rod 180. The spring axis 204 is accordingly aligned with the moving pivot axis 162 associated with the swing arm 152.

The biasing spring 200 can include two angularly spaced spring legs including a first spring leg 206 and a second spring leg 208 that radially extend from the helical coils 202 and that angularly diverge from each other. To connect with actuation linkage 148, the first spring leg 206 can extend from an upper axial of the helical coil 202 along and parallel with the first coupler link 190. To fixedly retain the first spring leg 206, the first coupler link 190 may include a buckle 210 or similar feature located along the length. To connect with one of the louvers 142, the second spring leg 208 may extend from the lower axial end of the helical coil parallel with the swing arm 152 and can be fixedly retained in a buckle 212 formed on the swing arm 152. Other structural features for fixedly retaining the first and second spring legs 206, 208 may include notches, catches, hooks, etc. Moreover, the spring legs may be retained to other parts of the louvers 142 and/or the actuation linkage 148.

When the ventilation assembly 130 is in the closed configuration, shown in FIG. 8, the biasing spring 200 may be in a normally relaxed state and the first and second spring legs 206, 208 may angularly diverge from each other in correspondence to the relative positions of the swing arm 152 and the first coupler link 190. When the ventilation assembly 140 is moved to the opened configuration by displacement of the pushrod 170 in the installation direction 114, the swing arm 152 and the first coupler link 190 are angularly moved into parallel alignment in response to articulation of the actuation linkage 148 and swinging of the louvers 142. The first and second spring legs 206, 208 are angularly moved together, placing the biasing spring 200 in a compressed state and storing mechanical energy for later release.

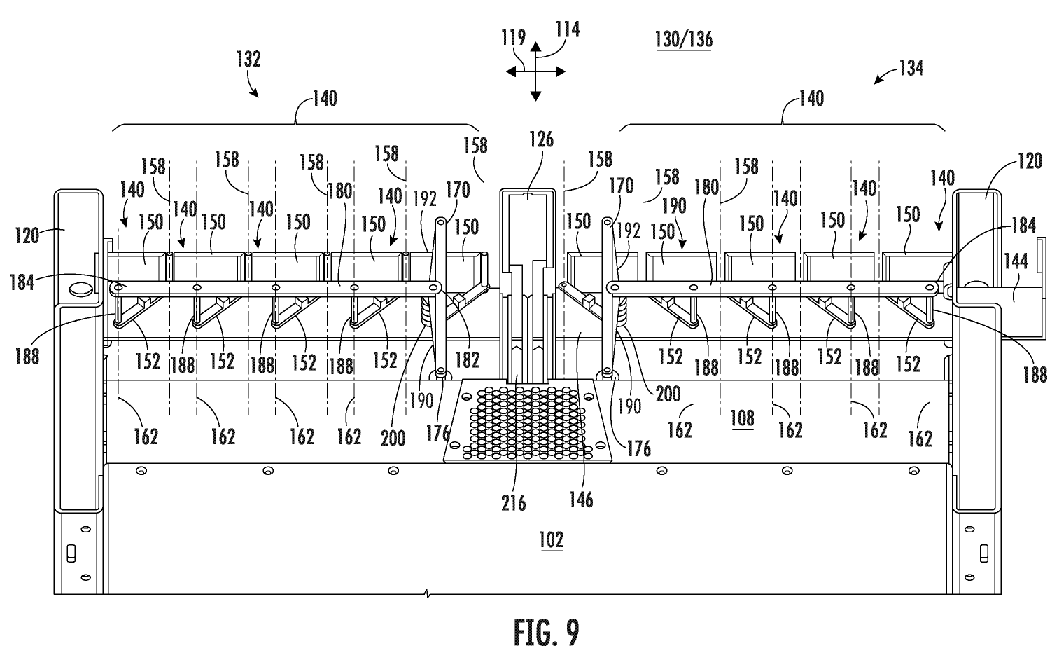

Referring to FIG. 9, which shows the ventilation assembly 130 attached to the rack rear face 118 of the storage rack 100, the ventilation assembly 130 may be in the closed configuration 136 prior to installation of the computing system 102 or another component into the receiving bays 110. In the closed configuration 136, each of the louvers 142 of the louver subassembly 140 is pivotally swung into coordinated alignment with the lateral direction 119. The louver panes 150 are perpendicular to the installation direction 114. As shown, the louver panes 150 of the plurality of louvers 142 aligned in the lateral direction 119 to close or occlude the receiving bays 110 from the rack rear face 118.

The louvers 142 are maintained in the closed configuration 136 by the biasing springs 200 associated with actuation linkage 148. Moreover, the biasing springs 200 articulate the actuation linkage 148 so the pushrods 170 are directed forwardly in the installation direction into the receiving bays 110 of the storage rack 100. When the computing system 102 is inserted rearwardly into the receiving bay 110 in the installation direction 114, the rollers 176 connected to the proximal ends 172 of the pushrods 170 make abutting contact with the chassis rear 108.

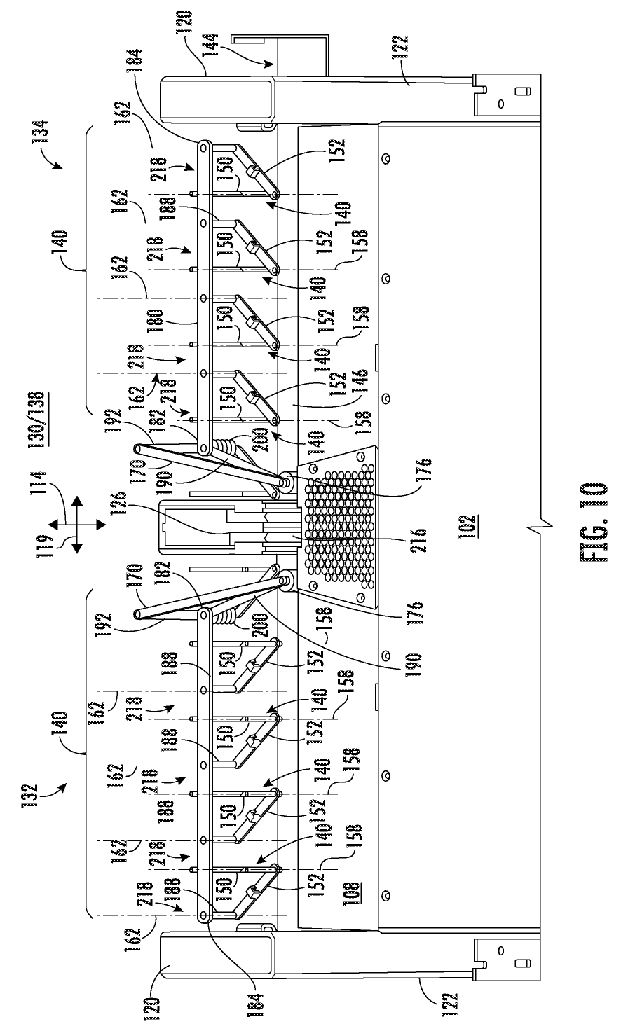

Referring to FIG. 10, continued insertion of the computing system 102 into the receiving bay 110 will displace the pushrods 170 in the installation direction 114 due to contact between the chassis rear 108 and the rollers 176. The rollers 176 associated with the first and second assembly halves 132, 134 of the ventilation assembly 130 may also be driven laterally towards each other with respect to the lateral direction 119. When rollers 176 connected to the proximal ends 172 of the pushrods 170 are driven laterally inwards, the pushrod 170 may tilt with respect to the installation direction 114. The rotational connection between the rollers 176 and the proximal end 172 of the pushrods 170 enables the lateral movement of the rollers with respect to the chassis rear 108.

When the pushrods 170 are displaced and tilted in the installation direction 114, the first and second coupler links 190, 192 can articulate with respect to each other. Because the first and second coupler links 190, 192 are commonly connected to the connecting rod 180 at the first lateral end 182 of the connecting rod 180, motion of the first and second coupler links 190, 192 causes the connecting rod 180 to translate linearly with respect to the lateral direction 119 while also being displaced with respect to the installation direction 114 due to being indirectly joined to the pushrod 170.

Motion of the connecting rod 180 is transferred to the swing arm 152 through the operative connection established by the connecting axles 188. Because each of the louvers 142 are spatially fixed with respect to the louver frame 144 at the fixed pivot socket 154, the louvers 152 are caused to swing outwardly with the louver panes 150 pivoting into parallel alignment with the installation direction 114. Pivoting the plurality of louvers 142 into parallel alignment creates a plurality of louver gaps 218 that are laterally spaced apart and that provide access through the louver subassembly 140 into the receiving bay 110. The widths of the louver gaps 218 in the lateral direction 119 can correspond to the pintle spaces 166 in FIG. 5. Hot air can flow outwardly from the receiving bays 110 along the installation direction 114 through the louver gaps 218. In possible configurations, the plurality of louvers 142 may not pivot to be completely parallel to the installation direction in the opened configuration 138, but may be slanted with respect to the installation direction 114. The plurality of louver gaps 218 accordingly may be slanted with respect to the installation direction 114. The closed and opened configurations described herein are relative to each other in that the closed and opened configurations relatively block or relatively permit airflow through the ventilation assembly.

With continued reference to FIGS. 9 and 10, when the computing system 102 is removed from the receiving bay 110, the biasing springs 200 can cause the ventilation assembly 130 to return to the closed configuration 132. For example, when the computing system 130 is move forwardly in the installation direction 114, the actuation forces applied to and displacing the rollers 176 is removed allowing the pushrods 170 to move forwardly in the installation direction 114. The stored energy in the biasing springs 200 that are compressed between the first coupler link 190 and the swing arm 152 of the louver 142 causes the actuation linkage 148 to articulate in manner moving the pushrod 170 forwardly in the installation direction 114 and pivoting the swing arm 152 about the fixed pivot axis 158 associated with fixed pivot socket 156.

Pivoting of the swing arms accordingly swings the louver panes 150 back into alignment with respect to the lateral direction 119 closing the plurality of louver gaps 218 in the ventilation assembly 130. The plurality of louvers 142 can be prevented from further pivoting with respect to fixed pivot axis 158 by structural features such as bumps located on the louver frame 144.

In the embodiments where the ventilation assembly 130 is split into the first and second assembly halves 132, 134, the louver subassemblies 140 can be arranged to mirror each other such that the plurality of louvers 142 pivotally swing open in opposite directions with respect to the lateral direction 119. Referring to FIGS. 1, 9 and 10, the louver frame 144 of the ventilation assembly 130 may be recessed into the rack rear face 130 so that the plurality of louvers 142 are able to pivot without colliding with external objects. The plurality of louvers 142 may swing outwardly from the receiving bay 100 as illustrated but may also configured to swing inwardly into the receiving bays or in different directions altogether.

The ventilation assembly 130 thus automates switching between the closed and opened configurations of the louver subassemblies 140 by insertion and removal of the computing system 102 into the receiving bays 110. Actuation does not require separate or additional activity or require the insertion of hands or objects into the receiving bays 110. As the computing system 102 is installed in the installation direction 114, the actuation linkage 148 converts that motion to an actuating force swinging the plurality of louvers 142 opened and allowing ventilation of the receiving bays 110. When the computing system 102 is removed, the biasing springs 200 swing the louvers 142 back to the closed configuration using energy stored during the previous installation of the computing system. The empty receiving bay 110 is blocked from airflow, improving ventilation by isolating the empty receiving bay and preventing airflow from bypassing other computing systems in the storage rack.

If the storage rack 100 includes a busbar 126 attached to the rack rear face 118 midway in the lateral direction 119, splitting of the ventilation assembly 130 into the first and second assembly halves 132, 134 allows access to the busbar 126 from the receiving bays 110. Accordingly, when a computing system 102 is inserted into the receiving bay 110 in the installation direction 114 through the rack front face 116, the busbar 126 is positioned to electrically connect with a corresponding electrical connector 216 protruding from the chassis rear 108 of the computing system.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A storage rack comprising:
a framework comprising a receiving bay for receiving a computing system inserted in an installation direction extending between a rack front face and a rack rear face;
a ventilation assembly at the rear rack face, the ventilation assembly comprising:
a louver frame extending in a lateral direction perpendicular to the installation direction;
a louver subassembly comprising a plurality of louvers each pivotally joined to the louver frame, the louver subassembly configurable between a closed configuration with the plurality of louvers at least partially occluding the receiving bay and an opened configuration with the plurality of louvers pivoted to provide louver gaps accessing the receiving bay; and
an actuation linkage operatively configured to convert motion in the installation direction to pivot each of the plurality of louvers between the closed configuration and the opened configuration.

2. The storage rack of claim 1, wherein the actuation linkage comprises a pushrod displaceable in the installation direction and a connecting rod connecting each of the plurality of louvers, the pushrod and the connecting rod being operatively connected to each other.

3. The storage rack of claim 2, wherein the actuation linkage comprises a first coupler link and a second coupler link connecting the pushrod and the connecting rod.

4. The storage rack of claims claim 3, wherein the pushrod comprises a distal end connected to the first coupler link and a proximal end connected to the second coupler link.

5. The storage rack of claim 4, wherein the actuation linkage comprises a roller journaled to the proximal end.

6. The storage rack of claim 1, wherein each of the plurality of louvers comprises a louver pane and a swing arm intersecting at a fixed angle.

7. The storage rack of claim 6, wherein pivoting of the plurality of louvers swings the louver panes respectively from being perpendicular to the installation direction in the closed configuration to being parallel to the installation direction in the opened configuration.

8. The storage rack of claim 7, wherein the louver panes of each of the plurality of louvers are aligned in the lateral direction in the closed configuration.

9. The storage rack of claim 6, wherein each of the plurality of louvers is connected by a connecting axle to a connecting rod operatively associated with the actuation linkage.

10. The storage rack of claim 1, wherein the actuation linkage further comprises a biasing spring biasing the louver subassembly to the closed configuration.

11. A method of ventilating a storage rack defining at least one receiving bay comprising
inserting a computing system into a receiving bay in an installation direction extending between a rack front face and a rack rear face;
moving a pushrod of a ventilation system in the installation direction in response to abutting contact with the computing system;
converting movement of the pushrod in the installation direction to movement of a connecting rod of the ventilation system in a lateral direction; and
pivoting a plurality of louvers, each of the plurality of louvers operatively connected to the connecting rod, from a closed configuration substantially parallel with the lateral direction to an opened configuration substantially parallel with the installation direction.

12. The method of claims claim 11, further comprising compressing a biasing spring operatively connecting between the pushrod and a louver subassembly comprised of the plurality of louvers by movement of the pushrod.

13. The method of claim 13 further comprising pivoting the plurality of louvers from the opened configuration to the closed configuration by releasing the biasing spring.

14. The method of claim 11, wherein the installation direction and the lateral direction are perpendicular to each other.

15. A ventilation assembly for a storage rack comprising:
a louver frame extending in a lateral direction and mountable between two vertical posts of a rack frame;
a louver subassembly comprising a plurality of louvers each pivotally joined to the louver frame, each of the plurality of louvers comprises a louver pane and a swing arm intersecting each other at a fixed angle, each of the plurality of louvers swingable to pivot the louver panes from being parallel in the lateral direction in a closed configuration to an opened configuration; and
an actuation linkage comprising a pushrod displaceable in an installation direction and a connecting rod connecting the plurality of louvers, the pushrod and the connecting rod operatively connected so that displacement of the pushrod in the installation direction swings each louver pane of the plurality of louvers from the closed configuration to the opened configuration.

16. The ventilation assembly of claim 15, wherein each louver pane of the plurality of louvers is parallel to the installation direction in the opened configuration.

17. The ventilation assembly of claim 16, wherein the lateral direction and the installation direction are perpendicular.

18. The ventilation assembly of claim 15, wherein the connecting rod moves in the lateral direction upon displacement of the pushrod in the installation direction.

19. The ventilation assembly of claim 15, wherein each swing arm is connected to the connecting rod by a connecting axle.

20. The ventilation assembly of claim 15, further comprising a biasing spring operatively connected between the louver subassembly and the actuation linkage to bias the plurality of louvers to the closed configuration.
